(19) United States
(12) Patent Application Publication
(10) Pub. No.: US 2020/0166791 A1
(43) Pub. Date: May 28, 2020

(54) Panel and method for manufacturing the same

(71) Applicant: InnoLux Corporation, Miao-Li County (TW)

(72) Inventor: Shao-Hong CHEN, Miao-Li County (TW)

(21) Appl. No.: 16/199,006

(22) Filed: Nov. 23, 2018

(51) Int. Cl. G02F 1/1343; H01L 27/12; H01L 29/786; H01L 29/66

(52) U.S. Cl. CPC G02F 1/13439; H01L 27/1222; H01L 27/124; G02F 1/1368; H01L 29/78669; H01L 29/66765; H01L 27/1262

(57) ABSTRACT

The present disclosure relates to a method for manufacturing a panel, including the following steps: providing a substrate; forming a first transparent conductive layer on the substrate; treating the first transparent conductive layer with a plasma including a gas with low reducing ability; and forming a first insulating layer on the first transparent conductive layer to obtain a panel, wherein a transparency of the panel is greater than or equal to 90% and less than 100%. The present disclosure further provides a panel manufactured by the aforesaid method of the present disclosure.

### BACKGROUND

### 1. Field

The present disclosure relates to a panel and a method for manufacturing the same. More specifically, the present disclosure relates to a panel with high transparency and a method for manufacturing the same.

### 2. Description of Related Art

Today, most electronic devices have one or more panels. In these panels, at least one transparent conductive layer is used which usually comprises a transparent conductive oxide, such as a metal oxide. However, the metal in the metal oxide is often reduced resulting in decreasing transparency of the panel.

Therefore, it is desirable to provide a panel and a method for manufacturing the same to reduce the aforesaid problems.

### SUMMARY

The present disclosure provides a method for manufacturing a panel, comprising the following steps: providing a substrate; forming a first transparent conductive layer on the substrate; treating the first transparent conductive layer with a plasma containing a gas with low reducing ability; and forming a first insulating layer on the first transparent conductive layer to obtain a panel, wherein a transparency of the panel is greater than or equal to 90% and less than 100%.

The present disclosure also provides a panel manufactured by the aforesaid method of the present disclosure, wherein the panel comprises: a substrate; a first transparent conductive layer disposed on the substrate; and a first insulating layer disposed on the first transparent conductive layer, wherein the first transparent conductive layer is treated with a plasma containing a gas with low reducing ability, and a transparency of the panel is greater than or equal to 90% and less than 100%.

The present disclosure further provides an electronic device, which comprises the aforesaid panel.

Other novel features of the disclosure will become more apparent from the following detailed description when taken in conjunction with the accompanying drawings.

### BRIEF DESCRIPTION OF THE DRAWINGS

FIG. 1A to FIG. 1D are cross-sectional view showing a process for forming a panel according to one embodiment of the present disclosure.

FIG. 2A to FIG. 2C are cross-sectional view showing a process for forming a panel according to another embodiment of the present disclosure.

### DETAILED DESCRIPTION OF EMBODIMENT

The following embodiments when read with the accompanying drawings are made to clearly exhibit the above-mentioned and other technical contents, features and/or effects of the present disclosure. Through the exposition by means of the specific embodiments, people would further understand the technical means and effects the present disclosure adopts to achieve the above-indicated objectives. Moreover, as the contents disclosed herein should be readily understood and can be implemented by a person skilled in the art, all equivalent changes or modifications which do not depart from the concept of the present disclosure should be encompassed by the appended claims.

Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

Furthermore, the terms recited in the specification and the claims such as “above”, “over”, or “on” are intended not only directly contact with the other element, but also intended indirectly contact with the other element. Similarly, the terms recited in the specification and the claims such as “below”, or “under” are intended not only directly contact with the other element but also intended indirectly contact with the other element.

Furthermore, the terms recited in the specification and the claims such as “connect” is intended not only directly connect with other element, but also intended indirectly connect or electrically connect with other element.

Furthermore, when a value is in a range from a first value to a second value, the value can be the first value, the second value, or another value between the first value and the second value.

Furthermore, the terms “about”, “nearly”, “almost”, “approximately”, or “substantially” are usually expressed within 20% within 10%, within 5%, within 3%, within 2%, within 1%, or within 0.5% of a given value or range. The quantity given here is an approximate quantity; that is, in the absence of specific descriptions of “about”, “nearly”, “almost”, “approximately”, or “substantially”, the meaning of “about”, “nearly”, “almost”, “approximately”, or “substantially” may still be implied. In addition, the features in different embodiments of the present disclosure can be mixed to form another embodiment.

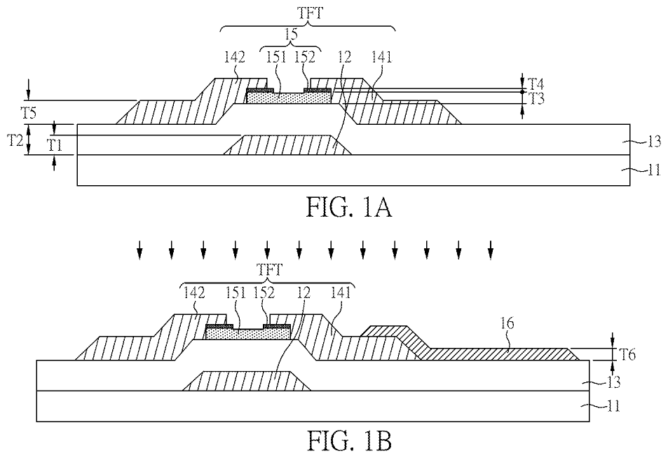

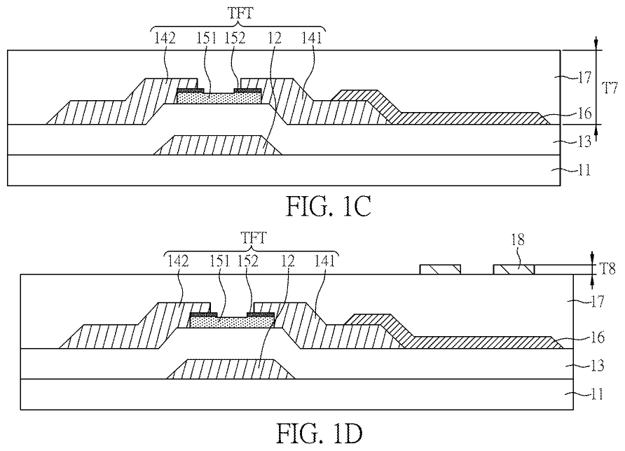

FIG. 1A to FIG. 1D are cross-sectional view showing a process for forming a panel according to one embodiment of the present disclosure.

As shown in FIG. 1A, a substrate 11 is provided. The substrate 11 can be a quartz substrate, a glass substrate, a wafer, a sapphire substrate, or etc. The substrate 11 also can be a flexible substrate or a film, and the material of which can comprise polycarbonate (PC), polyimide (PI), polypropylene (PP), polyethylene terephthalate (PET), other plastic or polymer material, or the combination thereof. However, the present disclosure is not limited thereto.

Next, a gate electrode 12 is formed on the substrate 11. The material of the gate electrode 12 may comprise metal (such as Cu, Al, Ti, Cr, or Mo), alloy thereof, metal oxide, metal nitrogen oxide, or other electrode materials, but the present disclosure is not limited thereto. In addition, the gate electrode 12 may have a single layer structure or a multi-layered structure. In one embodiment of the present disclosure, the gate electrode 12 may have a double-layered structure, wherein a bottom layer of the gate electrode 12 can be a Mo layer, and a top layer of the gate electrode 12 can be a MoN layer, but the present disclosure is not limited thereto. Furthermore, in one embodiment of the present disclosure, a thickness T1 of the gate electrode 12 can be in a range from 0.2 μm to 1 μm (0.2 μm≤T1≤1 μm), but the present disclosure is not limited thereto.

It should be noted that the term “a thickness of a specific layer” recited in the specification and the claims means the maximum thickness measured in a relatively flat region along a normal direction of the substrate.

Then, a second insulating layer 13 is formed on the substrate 11. The material of the second insulating layer 13 may comprise silicon oxide, silicon oxynitride, silicon nitride, aluminum oxide, resin, polymer, photoresist, or a combination thereof, but the present disclousre is not limited thereto. In one embodiment of the present disclosure, the material of the second insulating layer 13 may comprise silicon nitride, but the present disclosure is not limited thereto. In one embodiment of the present disclosure, a thickness T2 of the second insulating layer 13 can be in a range from 0.3 μm to 1 μm (0.3 μm≤T2≤1 μm), but the present disclosure is not limited thereto.

After the second insulating layer 13 is formed, a semiconductor layer 15 is formed on the second insulating layer 13. The material of the semiconductor layer 15 may comprise amorphous silicon, polycrystalline-silicon, or metal oxide such as IGZO (indium gallium zinc oxide), AIZO (aluminum indium zinc oxide), HIZO (hafnium indium gallium zinc oxide), ITZO (indium tin zinc oxide), IGZTO (indium gallium zinc tin oxide), or IGTO (indium gallium tin oxide), but the present disclosure is not limited thereto. In addition, the semiconductor layer 15 may have a single layer structure or a multi-layered structure. In one embodiment of the present disclosure, the semiconductor layer 15 can have a double-layered structure, wherein a bottom layer 151 can be an amorphous silicon layer, and a top layer 152 can be a doped amorphous silicon layer. In another embodiment of the present disclosure, the semiconductor layer 15 can have a single-layered structure, and the semiconductor layer 15 can be an amorphous silicon layer or a doped amorphous silicon layer. However, the present disclosure is not limited thereto. Furthermore, in one embodiment of the present disclosure, a thickness T3 of the bottom layer 151 can be in a range from 0.1 μm to 0.3 μm (0.1 μm≤T3≤0.3 μm), and a thickness T4 of the top layer 152 can be in a range from 0.02 μm to 0.05 μm (0.02 μm≤T4≤0.05 μm), but the present disclosure is not limited thereto.

Then, a first electrode 141 and a second electrode 142 are formed on the semiconductor layer 15, wherein the first electrode 141 and the second electrode 142 are electrically connected to the semiconductor layer 15 (especially the top layer 152 of the semiconductor layer 15). Thus, a transistor TFT is obtained, which comprises: the gate electrode 12, the semiconductor layer 15 disposed correspondingly to the gate electrode 12, and the first electrode 141 and the second electrode 142 electrically connected to the semiconductor layer 15. In some embodiments of the present disclosure, the first electrode is a source electrode, and the second electrode is a drain electrode. In other embodiments of the present disclosure, the first electrode is a drain electrode, and the second electrode is a source electrode, but the present disclosure is not limited thereto. The materials of the first electrode 141 and the second electrode 142 may comprise metal (such as Cu, Al, Ti, Cr, or Mo), alloy thereof, metal oxide, metal nitrogen oxide, other electrode materials, or the combination thereof, but the present disclosure is not limited thereto. In addition, the first electrode 141 and the second electrode 142 may have a single layer structure or a multi-layered structure, and similarly use the aforesaid materials. In another embodiment of the present disclosure, the first electrode 141 and the second electrode 142 may have a triple-layered structure, but the present disclosure is not limited thereto. Furthermore, in one embodiment of the present disclosure, thicknesses T5 of the first electrode 141 and/or the second electrode 142 can be in a range from 0.2 μm to 1 μm (0.2 μm≤T5≤1 μm), but the present disclosure is not limited thereto.

As shown in FIG. 1B, a first transparent conductive layer 16 is formed on the substrate 11. Herein, the transistor TFT is electrically connected to the first transparent conductive layer 16. The material of the first transparent conductive layer 16 may comprise any conductive material with high conductivity and high transparency. For example, the material of the first transparent conductive layer 16 may comprise a transparent conductive oxide, such as a metal oxide. Examples of the transparent conductive oxide may include, but is not limited to, ITO (indium tin oxide), IZO (indium zinc oxide), ITZO, IGZO, AZO (aluminum zinc oxide) or a combination thereof. In one embodiment of the present disclosure, the material of the first transparent conductive layer 16 may comprise ITO, but the present disclosure is not limited thereto. Furthermore, in one embodiment of the present disclosure, a thickness T6 of the first transparent conductive layer 16 can be in a range from 0.03 μm to 0.2 μm (0.03 μm≤T6≤0.2 μm), but the present disclosure is not limited thereto.

After the first transparent conductive layer 16 is formed, the first transparent conductive layer 16 is treated with a plasma. The H₂ plasma is often used to treat the first transparent conductive layer 16 as shown in FIG. 1B. However, the hydrogen ion in the H₂ plasma may reduce the metal comprised in the first transparent conductive layer 16, resulting in decreasing the transparency of the first transparent conductive layer 16.

Therefore, in the method of the present embodiment, the gas with low reducing ability is used to treat the first transparent conductive layer 16. In the present disclosure, “the gas with low reducing ability” refers to a gas with the ability to reduce the metal comprised in the first transparent conductive layer 16 lowered than the ability of H₂ to reduce the metal comprised in the first transparent conductive layer 16. In some embodiments of the present disclosure, the gas with low reducing ability may comprise, nitrous oxide (N₂O), oxygen (O₂), nitrogen (N₂), noble gas, such as argon (Ar) or helium (He), or a combination thereof, but the present disclosure is not limited thereto. Because the gas used in the present disclosure has lower reducing ability than H₂, the reduction of the metal comprised in the first transparent conductive layer 16 can be decreased. When the reduction of the metal comprised in the first transparent conductive layer 16 is decreased, the transparency of the first transparent conductive layer 16 can be improved, resulting in increasing transparency of the obtained panel.

After treating the first transparent conductive layer 16 with the plasma containing the gas with low reducing ability, a temperature of the substrate 11 can be increased. In addition, the time for applying the plasma, the power of the applied plasma, the gas contained in the applied plasma, and the gas flow of the applied plasma are not particularly limited, and can be adjusted according to the surface condition of the first transparent conductive layer 16 or the desired temperature of the substrate 11.

As shown in FIG. 1C, after treating the first transparent conductive layer 16, a first insulating layer 17 is formed on the first transparent conductive layer 16. The material of the first insulating layer 17 can be any material with high resistance, moisture barrier, and/or gas barrier. Examples of the first insulating layer 17 may comprise silicon oxide, silicon oxynitride, silicon nitride or a combination thereof, but the present disclosure is not limited thereto. Herein, the material used in forming the first insulating layer 17 can comprise SiH₄ or the compounds containing silicon, but the present disclosure is not limited thereto. In addition, the first insulating layer 17 can be formed by a deposition process such as a chemical vapor deposition process, but the present disclosure is not limited thereto. Furthermore, in one embodiment of the present disclosure, a thickness T7 of the first insulating layer 17 can be in a range from 0.3 μm to 1 μm (0.3 μm≤T7≤1 μm), but the present disclosure is not limited thereto. Herein, the thickness T6 of the first transparent conductive layer 16 is less than the thickness T7 of the first insulating layer 17.

As shown in FIG. 1D, after forming the first insulating layer 17, a second transparent conductive layer 18 is formed on the first insulating layer 17. The material of the second transparent conductive layer 18 is similar to that of the first transparent conductive layer 16, and is not repeatedly described herein. In addition, in one embodiment of the present disclosure, a thickness T8 of the second transparent conductive layer 18 can be in a range from 0.03 μm to 0.2 μm (0.03 μm≤T8≤0.2 μm), but the present disclosure is not limited thereto.

After the aforesaid process, a panel of the present embodiment is obtained, which comprises: a substrate 11, a first transparent conductive layer 16 disposed on the substrate 11, and a first insulating layer 17 disposed on the first transparent conductive layer 16. In addition, the panel of the present embodiment may further comprise: a second insulating layer 13 disposed between the first transparent conductive layer 16 and the substrate 11, a second transparent conductive layer 18 disposed on the first insulating layer 17, and a transistor TFT disposed on the substrate 11 and electrically connected to the first transparent conductive layer 16. Furthermore, the panel of the present embodiment may further comprise: a display medium layer (not shown in the figure) disposed on the second transparent conductive layer 18, and an opposite substrate (not shown in the figure) disposed opposite to the substrate 11, wherein the display medium layer is disposed between the substrate 11 and the opposite substrate.

In some embodiments of the disclosure, the panel may be a liquid crystal display (LCD) panel. For example, the LCD panel may be an in-plane switching (IPS) LCD panel or a fringe field switching (FFS) LCD panel, but the present disclosure is not limited thereto. In some embodiments of the present disclosure, the first insulating layer 17 is disposed between the first transparent conductive layer 16 and the second transparent conductive layer 18 to form a capacitance for triggering the rotation of liquid crystal molecules in the display medium layer.

In some embodiments, the first transparent conductive layer 16 is treated with the plasma containing the gas with low reducing ability, so the transparency of the panel can be greater than or equal to 90% and less than 100% (90%≤transparency<100%). In one embodiment, the transparency of the panel can be greater than or equal to 93% and less than or equal to 97% (93%≤transparency≤97%). In another embodiment, the transparency of the panel can be greater than or equal to 95% and less than or equal to 97% (95%≤transparency≤97%). It should be noted that the transparency of the panel is defined by measuring the TFT substrate of the panel, the structure of a TFT substrate is shown in FIG. 1D, but the present disclosure is not limited thereto. More specifically, the transparency of a TFT substrate is measured in the region with the first transparent conductive layer 16, but without opaque materials such as the metal electrodes (not shown) or metal wirings (not shown).

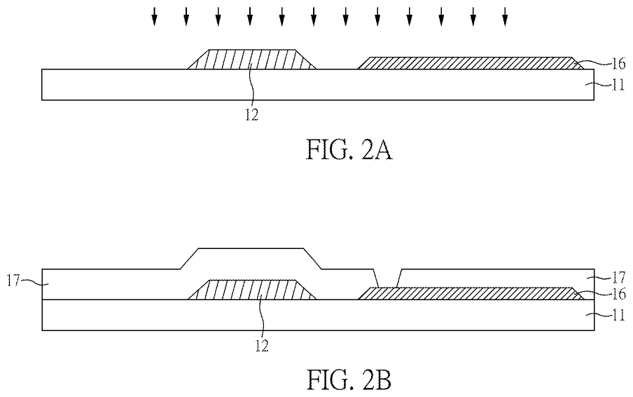

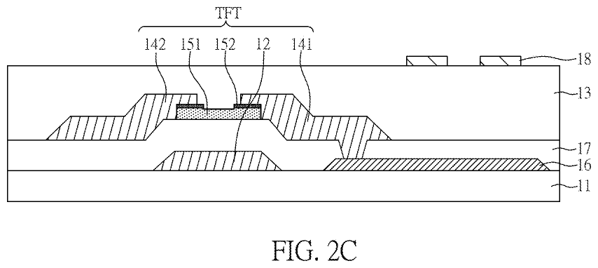

FIG. 2A to FIG. 2C are cross-sectional view showing a process for forming a panel according to another embodiment of the present disclosure.

The process for manufacturing the panel of the present embodiment is similar to that shown in the aforesaid embodiment shown in FIG. 1A to FIG. 1D, except for the following differences.

As shown in FIG. 2A, after forming the gate electrode 12 on the substrate 11, the first transparent conductive layer 16 is formed on the substrate 11, followed by treating the first transparent conductive layer 16 with a plasma containing a gas with low reducing ability. Next, as shown in FIG. 2B, a first insulating layer 17 is formed on the first transparent conductive layer 16 and the gate electrode 12, and the first insulating layer 17 has at least one via hole. Then, as shown in FIG. 2C, a transistor TFT is formed on the substrate 11 after forming the first insulating layer 17, and the transistor TFT is electrically connected to the first transparent conductive layer 16 through the via hole. Then, the second insulating layer 13 and the second transparent conductive layer 18 are sequentially formed to obtain the panel of the present embodiment.

The features (for example, the materials or the thicknesses of each layers, the process for forming each layers of the panel and the process for treating the first transparent conductive layer 16) of the present embodiment shown in FIG. 2A to FIG. 2C are similar to those of the aforesaid embodiment shown in FIG. 1A to FIG. 1D, and are not repeatedly described herein. The present disclosure also provides an electronic device with a highly transparent panel, which may comprised any one of the panel illustrated above (for example, the panel shown in FIG. 1D or FIG. 2C), wherein the panel comprises a substrate 11, a first transparent conductive layer 16 disposed on the substrate 11, and a first insulating layer 17 disposed on the first transparent conductive layer 16. Herein, the first transparent conductive layer 16 is treated with a plasma containing a gas with low reducing ability, and a transparency of the panel is greater than or equal to 90% and less than 100%.

In the aforesaid embodiments, a panel such as a display panel is disclosed to be applied in a display device. However, the present disclosure is not limited thereto. In particular, the process that the transparent conductive layer is treated with a plasma containing a gas with low reducing ability and then an insulating layer is formed on the treated transparent conductive layer can be applied to a panel of any other electronic device such as a touching device, a sensing device, a lighting device or other device with an insulating layer disposed on a transparent conductive layer to obtain a panel with high transparency.

Although the present disclosure has been explained in relation to its embodiment, it is to be understood that many other possible modifications and variations can be made without departing from the spirit and scope of the disclosure as hereinafter claimed.

What is claimed is:

1. A method for manufacturing a panel, comprising the following steps:
providing a substrate;
forming a first transparent conductive layer on the substrate;
treating the first transparent conductive layer with a plasma containing a gas with low reducing ability; and
forming a first insulating layer on the first transparent conductive layer, wherein a transparency of the panel is greater than or equal to 90% and less than 100%.

2. The method of claim 1, wherein the transparency of the panel is greater than or equal to 93% and less than or equal to 97%.

3. The method of claim 1, wherein reducing ability of the gas is weaker than reducing ability of H₂.

4. The method of claim 3, wherein the gas comprises N₂O, Ar, O₂, N₂, He, or a combination thereof.

5. The method of claim 1, wherein a thickness of the first transparent conductive layer is less than a thickness of the first insulating layer.

6. The method of claim 1, further comprising a step of forming a second insulating layer between the step of providing the substrate and the step of forming the first transparent conductive layer on the substrate.

7. The method of claim 1, further comprising a step of forming a second transparent conductive layer on the first insulating layer after the step of forming the first insulating layer on the first transparent conductive layer.

8. The method of claim 1, further comprising a step of forming a transistor on the substrate before or after the step of forming the first transparent conductive layer on the substrate, wherein the transistor is electrically connected to the first transparent conductive layer.

9. The method of claim 1, wherein a material of the first transparent conductive layer comprises ITO, IZO, ITZO, IGZO, AZO or a combination thereof.

10. A panel, comprising:
a substrate;
a first transparent conductive layer disposed on the substrate; and
a first insulating layer disposed on the first transparent conductive layer,
wherein the first transparent conductive layer is treated with a plasma containing a gas with low reducing ability, and a transparency of the panel is greater than or equal to 90% and less than 100%.

11. The panel of claim 10, wherein the transparency of the panel is greater than or equal to 93% and less than or equal to 97%.

12. The panel of claim 10, wherein reducing ability of the gas is weaker than reducing ability of H₂.

13. The panel of claim 12, wherein the gas comprises N₂O, Ar, O₂, N₂, He, or the combination thereof.

14. The panel of claim 10, wherein a thickness of the first transparent conductive layer is less than a thickness of the first insulating layer.

15. The panel of claim 10, further comprising a second insulating layer disposed between the first transparent conductive layer and the substrate.

16. The panel of claim 10, further comprising a second transparent conductive layer disposed on the first insulating layer.

17. The panel of claim 10, further comprising a transistor disposed on the substrate.

18. The panel of claim 17, wherein the transistor is electrically connected to the first transparent conductive layer.

19. The panel of claim 10, wherein a material of the first transparent conductive layer comprises ITO, IZO, ITZO, IGZO, AZO or a combination thereof.

20. An electronic device, comprising:
a panel, comprising:
a substrate;
a first transparent conductive layer disposed on the substrate; and
a first insulating layer disposed on the first transparent conductive layer,
wherein the first transparent conductive layer is treated with a plasma containing a gas with low reducing ability, and a transparency of the panel is greater than or equal to 90% and less than 100%.
